(19) United States
(12) Patent Application Publication
(10) Pub. No.: US 2019/0293864 A1
(43) Pub. Date: Sep. 26, 2019

(54) FRONTEND INTEGRATION OF ELECTRONICS AND PHOTONICS

(71) Applicant: UNIVERSITY COURT OF THE UNIVERSITY OF ST ANDREWS, St Andrews (GB)

(72) Inventors: Kapil DEBNATH, Southampton (GB); William WHELAN-CURTIN, St Andrews (GB)

(21) Appl. No.: 16/339,827

(22) PCT Filed: Oct. 5, 2017
(86) PCT No.: PCT/GB2017/053020

§ 371 Date: Apr. 5, 2019

(30) Foreign Application Priority Data
Oct. 6, 2016 (GB) 1617009.4

(51) Int. Cl. G02B 6/122; H01L 21/8238; G02B 6/136; G02B 6/42

(52) U.S. Cl. CPC G02B 6/122; H01L 21/8238; G02B 2006/12176; G02B 6/42; G02B 6/136

(57) ABSTRACT

A method of manufacturing a platform (10) for an integrated electronic and optical circuit comprises forming at least one optical device portion in a CMOS compatible substrate (12), wherein the optical device portion comprises a waveguide layer (22) and a barrier layer (20) arranged to confine light to a region of the waveguide layer, wherein forming the at least one optical device potion comprises: forming at least one trench (14) in the substrate (12); depositing the barrier layer (20) in the at least one trench (14); depositing the waveguide layer (22) over the barrier layer (20), and planarizing the substrate (12).

### INTRODUCTION

The present invention relates to a platform for an integrated electronic and optical circuit.

### BACKGROUND

Quick and cheap movement of information has become a keystone of our modern lifestyle. As a result there is an unprecedented increase in demand for data transfer and storage driving the development of servers and computer systems. The performance of Complementary Metal Oxide Semiconductor (CMOS) processors increases every year. A bottleneck for the Information and Communication industries is the high power consumption of copper interconnects (the traces that move information around and on/off the chip) at high speeds and over long distances, as copper cables reach their physical limits.

Optical interconnects are seen as the solution to this problem. Electrical data generated from electronic circuitry is encoded into a beam of light using an electro-optical modulator, transmitted via an optical cable/waveguide and converted back into electrical data using photo-detectors at the receiving end. Unlike an electrical wire, the limit on data transmission in an optical waveguide can be as high as 100 Tbit/s and data transfer at high bit rates is much more energy efficient. Silicon is a promising platform for optical interconnects due to the low cost fabrication of photonic components on silicon and the added possibility for direct integration of photonic components with electronic components.

In recent years, several techniques for optical-electronic integration have been both proposed and demonstrated including wire bonding, flip-chip bonding and monolithic integration. Wire bonding and flip-chip bonding require the use of bonding wires and pads which introduce parasitic capacitances and or are liable to degrade and hence limit the overall performance of the system and integration density (the number of components integrated in a given area). Monolithic integration in the frontend of CMOS technology involves fabricating photonic devices such as modulators, detectors and routing circuits next to electronic components such as transistors. Monolithic integration permits the shortest possible electronic interconnects between photonic and electronic components and therefore provides an increased integration density.

However, a material incompatibility arises when combining electronics and photonics on the same silicon platform. In particular, for conventional silicon or dielectric based photonic circuits a lower cladding (in the form of a thick buried oxide layer) is required to guide light. However, when integrated with electrical circuits such a layer traps heat in the electrical components, for example the transistors, thus reducing the integration density. This is unacceptable to the electronics industry.

Currently there are two approaches proposed for front-end integration of photonic circuits with electronics on bulk silicon substrate. The first is based on 3D integration of photonic circuits onto a bulk silicon substrate (A. Biberman et al., J. Emerg. Technol. Comput. Syst., vol. 7, pp. 7:1-7:25, 2011). In this approach, electronic components such as transistors are fabricated in the bulk silicon substrate and photonic components are fabricated in polysilicon or silicon compounds layers deposited on top of the bulk silicon substrate separated by spacer layers. This technique allows multiple layers of photonic circuits to be formed above the electronic circuits. In this approach, the backend thermal budget (the amount of thermal energy transferred to the wafer) of the photonic fabrication process may prohibit fabrication or damage the fabrication of metallisation layer(s). Another approach takes the fabrication of photonic circuits further into an electronic fabrication process flow (D. Thomson et al., Laser & Photonics Reviews vol. 8, pp. 180-187, 2014). In this approach, opto-electronic integration is achieved on a SOI platform, where both the electronic and photonic components are realized on the same platform. A problem with this is that it relies on silicon that is epitaxially grown on the SOI platform, which is very complex and increases wafer costs.

### SUMMARY

According to the present invention, there is provided a method of fabricating a platform for an integrated electronic and optical circuit comprising: forming at least one optical device portion in a substrate configured to accommodate CMOS circuitry, wherein the optical device portion comprises a waveguide layer and a barrier layer arranged to confine light to a region of the waveguide layer. The barrier layer may be in the form of a cladding layer.

Forming at least one optical device portion may involve forming at least one trench in the substrate; depositing the barrier layer in the at least one trench; and depositing the waveguide layer over the barrier layer.

Forming the at least one optical device portion may involve planarizing the substrate after deposition of the barrier and waveguide layers. Planarizing the substrate may involve removing portions of the barrier layer and the waveguide layer not in the trench such that the surface of the substrate is exposed.

Planarizing the substrate may comprise chemical and/or mechanical polishing.

Forming the at least one trench may comprise etching the at least one trench in the substrate.

The barrier layer may have a thickness of 450 nm or greater. Preferably, the barrier layer may have a thickness of 2000 nm. The barrier layer may comprise silicon dioxide.

The waveguide layer may have a thickness greater than 50 nm, preferably 200-250 nm. The waveguide layer may comprise polycrystalline silicon and/or germanium and/or silicon germanium.

The waveguide layer may be deposited on the barrier layer in one form and post processed to take on another form. For example, the waveguide layer may be deposited as amorphous silicon and processed post deposition to form polycrystalline silicon.

The method may further involve fabricating one or more optical components on or within the at least one optical device portions. The one or more optical components may comprise at least one of: a ring resonator, a grating coupler, a photonic crystal waveguide, a photodetector and an electro-optical modulator.

The method may further involve fabricating electronic components on the CMOS compatible substrate subsequent to fabricating the one or more optical components.

The CMOS compatible substrate may comprise a silicon substrate. In particular, the CMOS compatible substrate may comprise bulk silicon.

According to another aspect of the invention, there is provided an integrated electronic and optical circuit comprising:
a CMOS compatible substrate;
at least one electronic component on the CMOS compatible substrate;
at least one optical device portion in a trench formed in the CMOS compatible substrate, wherein the at least one optical device portion comprises a waveguide layer and a barrier layer arranged to confine light to a region of the waveguide layer, and
at least one optical component in or on the optical device portion.

Multiple trenches may be formed. One or more trenches may have different dimensions. For example, one or more trenches may have different depths.

### BRIEF DESCRIPTION OF THE DRAWINGS

Various aspects of the invention will now be described by way of example only, and with reference to the accompanying drawings, of which:

FIG. 1 is a cross-section through a platform for an integrated electronic and optical circuit, and

FIG. 2 is a schematic diagram showing a fabrication method of the platform for an integrated electronic and optical circuit.

### DETAILED DESCRIPTION OF THE DRAWINGS

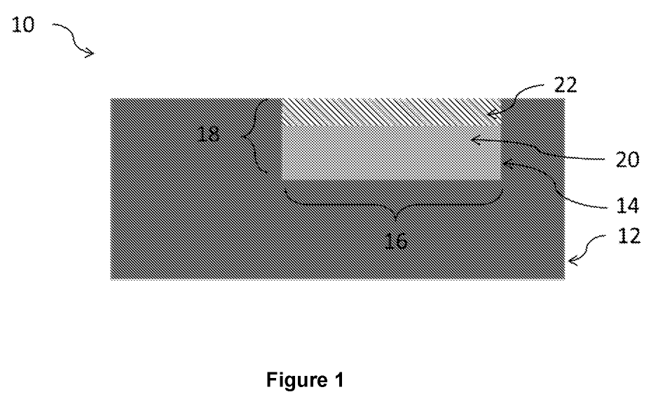

FIG. 1 shows a cross sectional view of a platform 10 for an integrated electronic and optical circuit. The platform 10 has a bulk silicon substrate 12 that has a trench 14 with a width 16, a height 18 and a length. The bulk silicon substrate 12 is suitable for CMOS circuits to be formed thereon. On the substrate 12 and in the trench 14, there is a barrier layer 20, for example a silicon dioxide layer. On the barrier layer 20 and inside the trench 14, there is an optical waveguide layer 22, for example, a polycrystalline silicon layer.

The barrier layer 20 has a lower refractive index than the optical waveguide layer 22. The barrier layer 20 has a width equal to the trench width 16. The optical waveguide layer 22 has a width equal to the trench width 16. The sum of the barrier layer height 20 and the optical waveguide layer height 22 is substantially equal to the trench height 18 such that the top surface of the optical waveguide layer 22 is flush with the top surface of the bulk silicon substrate 12. The barrier layer 20 is thick enough to confine light to the waveguide layer 22. The thickness of the barrier layer 20 is typically in the range 1-3 micron. The thickness of the optical waveguide layer 22 is typically in the range 200 nm-2 micron.

Together, the barrier layer 20 and the optical waveguide layer 22 form an isolated photonic device island in the silicon substrate 22. The photonic device island is configured to allow optical components to be formed therein or thereon. For example, components can be formed on the waveguide layer 22 or the layer 22 can be adapted or further processed to form optical components. Optical components can be passive and/or active photonic components. For example, the formed optical components can be ring resonators, photonic crystals, grating couplers, waveguides and electro-optical modulators. Multiple photonic device islands may be formed in the silicon substrate 22, each island having its own optical components.

Following the fabrication of optical components on the islands CMOS fabrication processes can be performed on the platform 10 to form electronic components. In this sense, the platform is fully CMOS compatible as the subsequent CMOS fabrication processes do not have an effect on the formed photonic circuit and equally the presence of the photonic island(s) does not interfere with the CMOS fabrication. The platform thus provides front-end integration with minimal changes to electrical device manufacturing processes currently in use (for example CMOS).

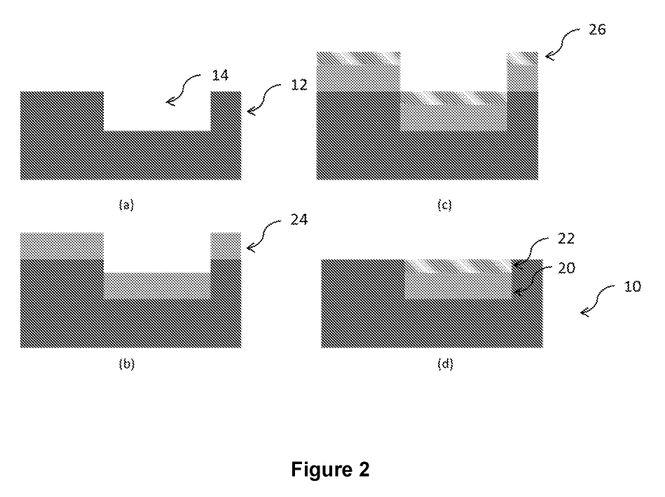

FIG. 2 shows four cross sectional views of a method for producing the platform 10 for an integrated electronic and optical circuit. FIG. 2(a) shows the result of a first step of etching the bulk silicon substrate 12 to a pre-determined depth, pre-determined width and pre-determined length to from the trench 14. The length and width define a trench area.

FIG. 2(b) shows a suitable barrier material, for example silicon dioxide, deposited over the platform 10 to produce a barrier layer 24, using a technique such as Low Pressure Chemical Vapour Deposition or Plasma Enhanced Chemical Vapour Deposition for example. The barrier layer 24 spans at least the trench area. The barrier material layer may be deposited to cover the entire area of the platform 10 or just an area around and including the trench 14. Deposition of the barrier material is controlled such that the thickness of the first barrier material layer 24 is less than the trench depth 18. The difference between the trench depth 18 and the thickness of the first barrier layer will define the thickness of the waveguide.

FIG. 2(c) shows a suitable waveguide material deposited on the first barrier material layer 24 to form a first waveguide material layer 26. The first waveguide material layer 26 must span at least the trench area. The deposition of the first waveguide layer 26 is controlled such that the waveguide material fills the remaining volume of trench 14. In other words, the depth of the barrier layer 24 and the waveguide layer 26 is at least equal to the depth of the trench 14 such that, together, the barrier layer 24 and the waveguide layer 26 at least fill the trench 14.

FIG. 2(d) shows removal of portions of the barrier layer 24 and the waveguide layer 26 not in the trench 14 by, for example, planarizing using chemical and/or mechanical polishing methods. Planarizing removes portions of the barrier layer 24 and the waveguide layer 26 not in the trench such the top surface of the bulk silicon substrate 12 is exposed. The bulk silicon substrate 12 and waveguide layer 22 thus form a plane.

Semiconductor processing techniques allow precise termination of this material removal step. Optionally, such processing techniques may include depositing a stop layer material over the substrate prior to etching the trench and depositing the barrier layer material to form a stop layer between the substrate and the barrier layer. The stop layer material is deposited over the entire area of the substrate. The stop layer material may be Titanium Nitride, Silicon Nitride or any suitable material. The first barrier layer and first waveguide layer are then deposited over the stop layer, as described with reference to FIGS. 2(b) and 2(c). The stop layer may be a chemical or mechanical polishing stop layer and/or an etch stop layer. The stop layer acts to terminate the polish planarization step of FIG. 2(d). In more detail, the equipment carrying out the planarization acts on the entire surface of the substrate. During this action, the portion of the waveguide layer 26 not in the trench is removed followed by the removal of the portion of the barrier layer 24 not in the trench. The planarization equipment detects the transition from the barrier layer 24 not in the trench to the portion of stop layer not in the trench and the planarization step is terminated in response to this transition.

Optionally, the waveguide material may be treated after this stage. For example, this would be necessary where the waveguide material used is amorphous silicon. In this case, the amorphous silicon would be processed using known techniques, such as annealing in a furnace at high temperature or by laser annealing to form polycrystalline silicon.

Once the excess barrier and waveguide material is removed and any post processing of the waveguide material is completed, the photonic device island is formed. At this stage, the top surface of the platform 10 is substantially flat and ready for the processing and formation of optical devices. Once this is done, electronic devices can be formed on the substrate using CMOS processes. Optical and electronic devices are connected as appropriate thereby to form an integrated electronic and optical circuit.

FIG. 1 and FIG. 2 show only a single photonic device island. However, it will be appreciated that one or more additional trenches may be etched on the platform 10 at other locations to create a pattern or array of photonic device islands. One or more additional trenches may be etched with different dimensions (depth and/or width and/or length) to the first trench.

Waveguides with different depths in different regions of the wafer may be formed. Etching trenches of different depths involves, for example, replacing the step shown in FIG. 2(a) with a first step of etching a first set of one or more trenches to a first depth and a second step of etching a second set of one or more trenches to a second depth. In this case, the steps of depositing waveguide and barrier material may overfill one of the two sets of trenches. However, the planarization step, described above, will remove any excess material such that the bulk silicon substrate and the waveguide layers of the first and second sets of trenches form a single plane.

Further alternatives are also possible. Solid phase epitaxy could be used to provide the waveguide layer. Other examples for materials suitable for the waveguide material may be, for example, Germanium or Silicon Germanium.

The platform 10 offers the advantage that electronic fabrication steps do not need to be modified from typical fabrication steps performed. In other words, CMOS fabrication can be performed subsequent to the formation of the isolated optical islands in the platform 10. It is anticipated that this will facilitate uptake by industry. In addition, photonic components can be subjected to testing prior to electronic fabrication steps. Electronic fabrication incurs considerable cost. It is therefore advantageous to eliminate problems with photonic component yield.

A skilled person will appreciate that variations of the enclosed arrangement are possible without departing from the invention. For example, in one embodiment, the shallow trench isolation and poly silicon processing steps used in advanced CMOS may be used to create the barrier layer and a waveguiding layer. A photonic crystal cavity may be formed in the polysilicon. A silica barrier layer and a dielectric waveguide may be formed above the polysilicon layer, and the photonic crystal cavity and dielectric waveguide may be designed to provide vertical coupling. Examples of how to implement this are described in WO 2013017814, the contents of which are incorporated herein by reference. A network of modulators, photodetectors, similar to Optics Express 20, 27420-27428 (2012) and Applied Physics Letters 102, 171106 (2013), the contents of which are incorporated herein by reference, and lasers using the approach of Optics Letters 41, 894-897 (2016), the contents of which are incorporated herein by reference, can be created thereby providing high bandwidth optical network on the electronics chip, that occupies a small fraction of the surface of the silicon wafer.

Accordingly, the above description of the specific embodiment is made by way of example only and not for the purposes of limitations. It will be clear to the skilled person that minor modifications may be made without significant changes to the operation described. For example, the bulk silicon substrate 12 can be any Complementary Metal Oxide Semiconductor (CMOS) compatible substrate.

What is claimed is:

1. A method of manufacturing a platform for an integrated electronic and optical circuit comprising:
forming at least one optical device portion in a CMOS compatible substrate, wherein the optical device portion comprises a waveguide layer and a barrier layer arranged to confine light to a region of the waveguide layer, wherein forming the at least one optical device portion comprises:
forming at least one trench in the substrate;
depositing the barrier layer in the at least one trench;
depositing the waveguide layer over the barrier layer, and
planarizing the substrate.

2. A method as claimed in claim 1 wherein forming the at least one trench comprises etching the at least one trench in the substrate.

3. A method as claimed in claim 1, wherein forming at least one trench comprises forming at least one trench having a first depth and forming at least one trench having a different depth.

4. A method as claimed in claim 1, wherein the barrier layer has a thickness greater than 450 nm.

5. A method as claimed in claim 1, wherein the barrier layer comprises silicon dioxide.

6. A method as claimed in claim 1, wherein the waveguide layer comprises polycrystalline silicon and/or germanium and/or silicon germanium.

7. A method as claimed in claim 1, wherein the waveguide layer is deposited on the barrier layer as amorphous silicon and processed post deposition to form polycrystalline silicon.

8. A method as claimed in claim 1, wherein planarizing the substrate involves removing portions of the barrier layer and the waveguide layer not in the trench such that the surface of the CMOS compatible substrate is exposed.

9. A method as claimed in claim 1, further comprising: fabricating one or more optical components on or within the at least one optical device portions.

10. A method as claimed in claim 9, wherein the one or more optical components comprises at least one of: a ring resonator, a grating coupler, a photonic crystal waveguide, a photodetector and an electro-optical modulator.

11. A method as claimed in claim 9, further comprising fabricating electronic components on the CMOS compatible substrate subsequent to fabricating the one or more optical components.

12. A method as claimed in claim 1, wherein the CMOS compatible substrate comprises a silicon substrate.

13. An integrated electronic and optical circuit comprising: a CMOS compatible substrate, at least one electronic component on the CMOS compatible substrate and at least one optical device portion in a trench formed in the CMOS compatible substrate, wherein the at least one optical device portion comprises a waveguide layer and a barrier layer arranged to confine light to a region of the waveguide layer.

14. A circuit as claimed in claim 13, wherein the trench is a first trench and further comprising a second optical device portion formed in a second trench, wherein the second trench has a depth different to the first trench.

15. A circuit as claimed in claim 13, wherein the integrated circuit comprises optical components within the optical device portion and electronic components on the surface of the CMOS compatible substrate.
